(19) United States
(12) Patent Application Publication
(10) Pub. No.: US 2006/0269787 A1
(43) Pub. Date: Nov. 30, 2006

(54) Organic light-emitting diode and method for manufacturing the same

(75) Inventors: Che-Jen Chen, Kaohsiung City (TW); Shi-Hao Li, Panchiao City (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/439,996

(22) Filed: May 25, 2006

(30) Foreign Application Priority Data
May 27, 2005 (TW) 94117436

(51) Int. Cl. H01L 51/54; H01L 51/56; H05B 33/12

(52) U.S. Cl. 428/690; 428/917; 313/504; 313/506; 427/66

(57) ABSTRACT

An organic light-emitting diode (OLED) includes a first electrode, an electron transport layer, an emitting layer, and a second electrode. The electron transport layer has at least one n-type dopant to enhance electron mobility. The n-type dopant includes an alkali halide, an alkaline-earth halide, an alkali oxide, or a metal-carbonate compound.

### BACKGROUND OF THE INVENTION

(1) Field of the Invention

This invention relates to an organic light-emitting diode and a method for manufacturing the same, and more particularly, to the organic light-emitting diode having an electron transport layer with an n-type dopant.

(2) Description of the Related Art

An organic light-emitting diode (OLED) display is composed mainly of OLEDs and driving transistors. The OLED is sorted into bottom emitting, inverted bottom emitting, top emitting, inverted top emitting, and double emitting. The difference between the normal OLED and inverted OLED is that the manufacturing process of the inverted OLED started by forming a cathode layer on a substrate, the organic layer and the anode layer follow. Since the cathode layer is formed on the substrate, it is easier to establish a connection between the cathode layer and the drain electrode of the driving transistor.

FIG. 1A shows a pixel structure of a typical OLED display and FIG. 1B shows a pixel structure of a typical inverted OLED display. As shown, the illumination of the OLEDs 20, 20a is decided by the potential difference between the gate electrode G and the source electrode S of the driving transistor 10. Therefore, a steady potential of the source electrode S is demanded for adjusting the potential of the gate electrode G to steadily control the illumination of the OLED 20, 20a.

The operating voltage of the OLED 20 shown in FIG. 1A, which connects to the source electrode S of the driving transistor 10, influences the steadiness of the potential at the source electrode S. In contrast, the OLED 20a of FIG. 1B connecting to the drain electrode D of the driving transistor 10 prevents the steadiness of the potential at the source electrode S from being affected by the operation voltage of the OLED 20a. In addition, as an n-channel thin film driving transistor (TFT) is used, the potential of the source electrode S must be maintained at the low level when the transistor is turned on. Since the source electrode S is in the low level, the current usually flows from the drain electrode D to the source electrode S within the transistor 10 and the cathode of the OLED should be used to connect to the drain electrode D of the driving transistor 10.

As shown in FIG. 1C, the inverted OLED 20a has a substrate 21, a cathode, 22, an anode 23, and an organic light-emitting layer 24 interposed between the cathode 22 and the anode 23. The cathode 22 is formed on the substrate 21 and has an LiF layer 221 and an Al layer 222.

The process for manufacturing the OLED display may be divided into two stages, the driving transistor manufacturing stage and the OLED manufacturing stage. As to the driving transistor manufacturing stage, the formation of driving transistors in the present development of active OLED display may be sorted as low temperature poly silicon TFT manufacturing process and amorphous silicon TFT manufacturing process. In the a-Si TFT manufacturing process, the deposited silicon needs not to be crystallized. Therefore, the problems due to the poor uniformity of crystallized grains, such as the illumination uniformity for large scale OLED, may be prevented. However, the a-Si TFT is usually an n-channel TFT with drain electrode connected to the OLED for displaying application. The cathode of the OLED includes the Al layer 222 and the LiF layer evaporated on the substrate 21 in a serial. It is noted that the Al layer 222 of the cathode of the OLED cannot be formed in the driving transistor manufacturing stage due to the high thermal expansion, which may form a hill structure under high temperature process.

FIG. 1D shows the process for manufacturing driving transistors of typical inverted OLED display. It is noted that as the Al layer 222 is formed in the driving transistor manufacturing stage, the hill structure 2221 may be formed in the high temperature steps to degrade the electronic property of the elements. In contrast, as the Al layer 222 is formed in the OLED manufacturing stage, an additional shadow mask for defining the conductive region is demanded. Thus, the complication and the cost of the process increase.

As mentioned, since the amorphous silicon TFT is usually an n-channel TFT, in order to prevent the operation of the a-Si TFT from being influenced by the operation voltage of the OLED, the OLED should be arranged at the drain electrode of the TFT and the technology of inverted OLED should be used. It is noted that cathode of the inverted OLED usually uses the metal materials with the work function close to the lowest unoccupied molecular orbital, or adds some alkali or alkaline earth compound to increase the injection of electrons. The electrodes may result in the difficulty of the process and a higher operation voltage of the OLED.

### SUMMARY OF THE INVENTION

It is a main object of the present invention to provide an OLED with enhanced illumination and reduced operation voltage by increasing the electron mobility of the electron transport layer.

The OLED provided in the present invention has a first electrode, an electron transport layer, an emitting layer, and a second electrode. After the first electrode formed on the substrate, the electrode transport layer is formed on the first electrode. The electrode transport layer has an n-type dopant. The emitting layer is formed on the electrode transport layer. The second electrode is formed on the emitting layer.

The structure may prevent the problem mentioned in the related art, for example, the manufacturing difficulty for forming the cathode in the driving transistor manufacturing stage may be overcame by using transparent conductive oxide (TCO), such as indium-tin-oxide (ITO), as the cathode of the inverted OLED. In addition, the operation voltage of the OLED may be lowered down to increase the operation efficiency by using the electron transport layer with an alkali or an alkaline-earth compound.

As the transparent cathode layer is formed in the driving transistor manufacturing stage, the hill structure mentioned in the related art may not be formed even under high temperature environment. In addition, as the transparent cathode layer is formed in the OLED manufacturing stage, the additional shadow mask is not needed for defining the conductive region.

### BRIEF DESCRIPTION OF THE DRAWINGS

The present invention will now be specified with reference to its preferred embodiment illustrated in the drawings, in which:

FIG. 1A is a schematic view showing a pixel structure of a typical OLED display;

FIG. 1B is a schematic view showing a pixel structure of a typical inverted OLED display;

FIG. 1C is a schematic view showing a typical inverted OLED;

FIG. 1D is a schematic view showing the hill structured formed under high temperature process within a typical inverted OLED display;

FIG. 2A is a schematic view showing a basic structure of the OLED in accordance with the present invention;

FIG. 2B is a diagram showing a relationship of current density versus operation voltage of the OLED;

FIG. 2C is a diagram showing a relationship of brightness versus operation voltage of the OLED;

FIGS. 3A to 3D are schematic views showing a preferred embodiment of the method for manufacturing the OLED in accordance with the present invention;

FIG. 3E is a schematic view showing another preferred embodiment of the OLED in accordance with the present invention;

FIG. 4 is a schematic view showing an inverted bottom emitting OLED in accordance with the present invention;

FIG. 5 is a schematic view showing an inverted top emitting OLED in accordance with the present invention; and

FIG. 6 is a schematic view showing a double emitting OLED in accordance with the present invention.

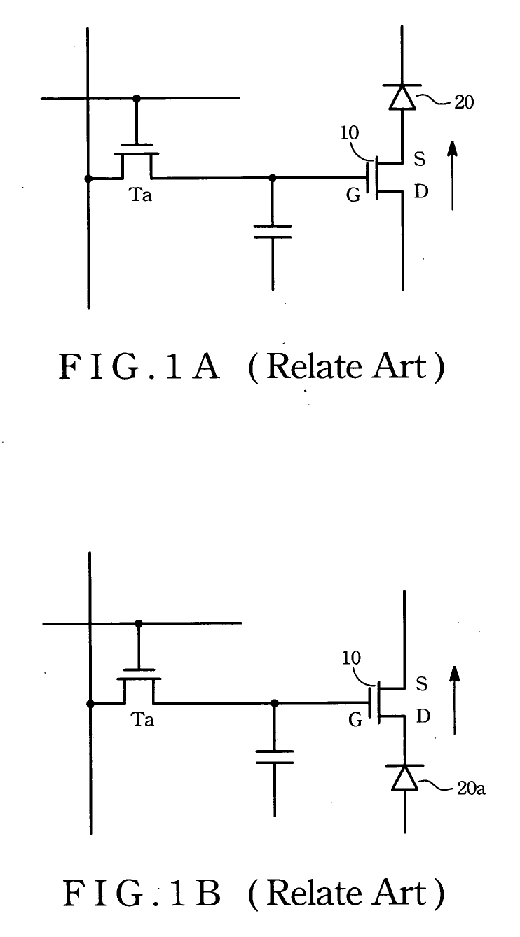

### DESCRIPTION OF THE PREFERRED EMBODIMENTS

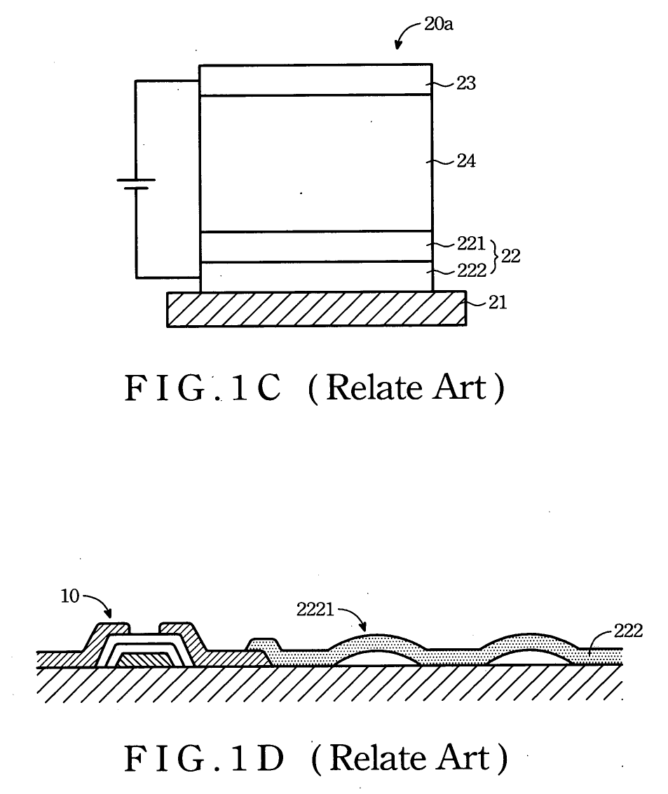

FIG. 2A shows a preferred embodiment of an OLED 30 in accordance with the present invention. The OLED 30 has a basic structure including a first electrode 32, an electron transport layer 33a, an emitting layer 34, and a second electrode 35. The first electrode 32 is formed on the substrate 31. The electron transport layer 33a is formed on the first electrode 32 and doped with at least one n-type dopant. The emitting layer 34 is formed on the electron transport layer 33a and includes monomers or polymers with fluorescence or phosphorescence characteristics. The second electrode 35 is formed on the emitting layer 34. As shown in FIG. 2A, after the formation of the emitting layer 34, a hole transport layer 37 and a hole injecting layer 36 may be selectively formed on the emitting layer 34. The hole transport layer 37 may be formed of allylamine group material, and the hole injecting layer 36 may be formed of phthalocyanine group material or organic material mixed with Lewis acid.

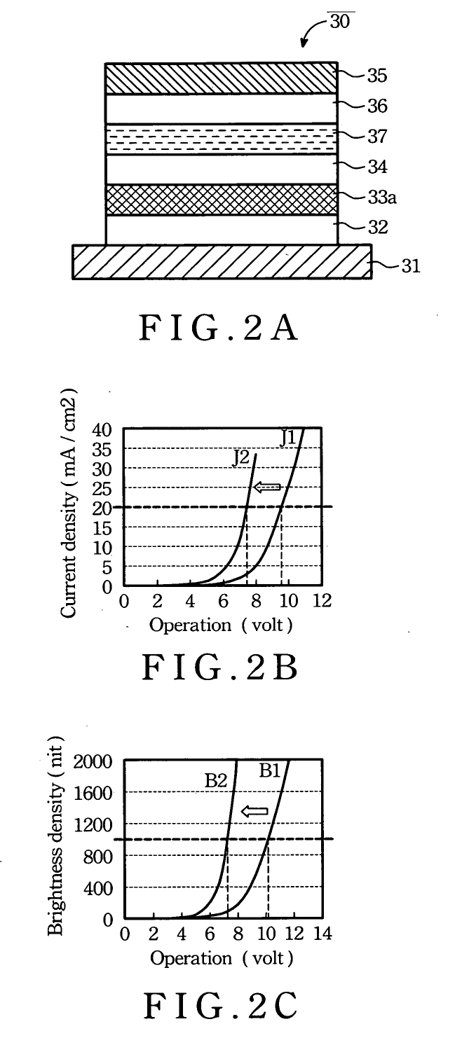

In the present embodiment, the electron transport layer 33a may be formed of (8-hydroxyquinolinolato) aluminum (Alq), 1,3,5-Tris (N-phenylbenzimidazol-2-yl)benzene (TPBI), derivatives of anthracene, or derivatives of fluorine, spirofluorine etc., mixed with n-type dopant such as an alkali halide, an alkaline-earth halide, an alkali oxide, or a metal-carbonate compound etc. to increase electron mobility thereof. An electron injecting layer 38 may be interposed between the first electrode 32 and the electron transport layer 33a as shown in FIG. 3E. The electron injecting layer 38 may be formed of metal compound with work function perfectly adapted to that of the first electrode 32, such as an alkali halide, an alkaline-earth halide, an alkali oxide, or a metal-carbonate compound, or an organic layer mixed with an n-type dopant.

In order to prevent the formation of the hill structure, the first electrode 32 formed on the substrate 31 should be formed of metal with good deformation resistance under high temperature. Thus, the first electrode 32 includes a transparent conductive oxides such as indium-tin-oxide (ITO), indium-zinc-oxide (IZO), zinc oxide, indium nitride, silicon dioxide, and etc. Since the second electrode 35 is connected to the hole transport layer 37 or the hole injecting layer 36, the second electrode 35 should be formed of the material with a work function substantially equal to the highest occupied molecular orbit (HOMO) level of the hole transport layer 37 or the hole injecting layer 36, such as Al, Al—Li alloy, Mg—Ag alloy, and etc..

FIGS. 2B and 2C show diagrams depicting relationship of current density versus operation voltage. The curve J1 indicates the variation of current density with respect to the operation voltage of a traditional OLED. The curve J2 indicates the variation of current density with respect to the operation voltage of a blue OLED in the present invention. The traditional OLED has an electron injecting layer and a cathode both formed of LiF/Al, wherein the thickness of Al is about 30 Å to ensure conductivity and transparency. The OLED in the present invention has an anode formed of silver, a cathode formed of ITO, an emitting layer, which may be a blue emitting layer, an electron transport layer mixed with an alkali metallic compound. As shown, it is noted that as the current density is 20 mA/cm2, the operation voltage of the OLED in the present invention is about 7.5V, whereas the operation voltage of the traditional OLED is about 9.5V. Thus, it may reduce the power consumption to use the OLED in the present invention in compared with the traditional OLED.

FIG. 2C shows a diagram depicting a relationship of brightness versus operation voltage. The curve B1 indicates the variation of brightness with respect to the operation voltage of a traditional OLED. The curve B2 indicates the variation of brightness with respect to the operation voltage of a blue OLED in the present invention. As the brightness is 1000 nits, the operation voltage of the OLED in the present invention is about 7V, whereas the operation voltage of the traditional OLED reaches about 10 V. Thus, the OLED in the present invention has better illumination efficiency, which is especially important for high brightness demand. It is noted that the result shown in FIG. 2B and FIG. 2C proves that the usage of ITO as the cathode is helpful for electron injecting, and the n-type dopant within the electron transport layer definitely can increase electron mobility.

FIGS. 3A to 3D show a process for manufacturing an OLED panel with the OLED provided in the present invention. The driving transistor manufacturing stage takes place first to form driving transistors 10 on the substrate 31. Then, the OLED manufacturing stage follows to form the OLEDs in accordance with the present invention. The process of this stage includes: forming the first electrode 32 on the substrate 31, wherein the first electrode 32 includes a transparent electrode material; then forming the electron transport layer 33a mixed with at least one n-type dopant on the first electrode 32, and the electron transport layer 33a may be formed by using evaporate method; then forming the emitting layer 34 on the electron transport layer 33a; and then forming the second electrode 35 on the emitting layer 34.

Taking the inverted OLED as an example, the first electrode 32 thereof may be a transparent conductive layer such as an ITO layer functioned as the cathode for connecting to the drain electrode of the driving transistor 10. An electron transport layer 33a mixed with an alkali halide, an alkaline-earth halide, an alkali oxide, or a metal-carbonate compound is formed on the ITO layer. It is noted that by selecting ITO to form the first electrode 32, the problem of high temperature deformation resistance may be promoted. Thus, the first electrode 32 may be formed in the driving transistor manufacturing stage together with the driving transistor 10. In addition, as shown in FIG. 3E, an electron injecting layer 38 may be selectively interposed between the first electrode 32 and the electron transport layer 33a for increasing electron injection ability. The electron injecting layer 38 may be formed of metallic compounds including an alkali halide, an alkaline-earth halide, an alkali oxide, or a metal-carbonate compound.

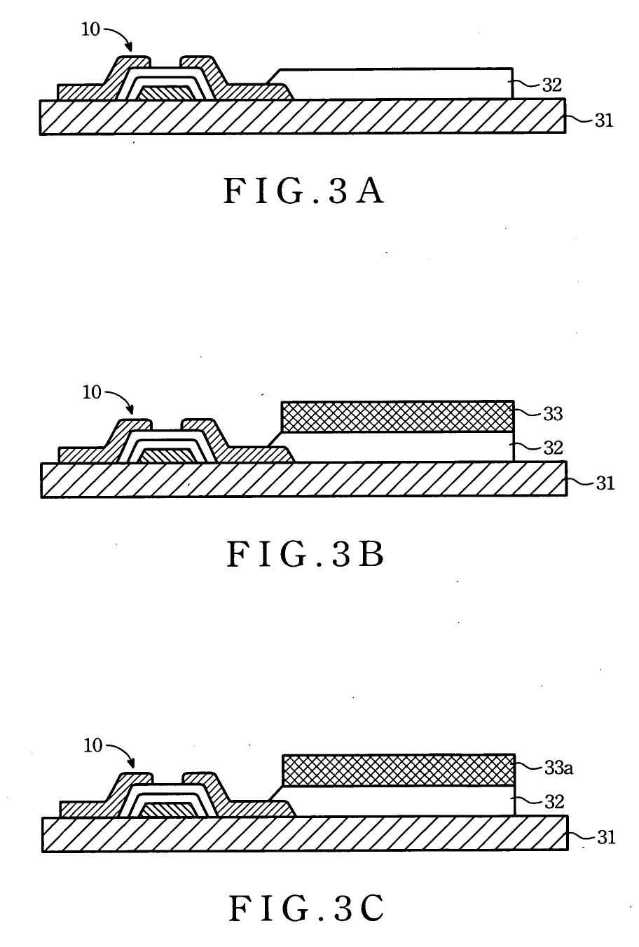

In addition, the formation of the hole transport layer 37 and the hole injecting layer 36 between the emitting layer 34 and the second electrode 35a as shown in FIG. 4 as well as the formation of electrode injection layer 38 between the first electrode 32 and the electron transport layer 33a as shown in FIG. 3E enhance the transportation of electrons and holes.

FIG. 4 shows an inverted bottom emitting OLED 40 in accordance with the present invention. The first electrode 32 of the OLED 40 is formed on the substrate 31. The first electrode 32 includes a transparent conductive material and connected to the negative electrode of the voltage source. The second electrode 35a includes a reflective conductive material for reflecting the illumination generated in the emitting layer 34 toward the substrate 31. In addition, an electrode transport layer 33a mixed with at least one n-type dopant in formed between the first electrode 32 and the emitting layer 34.

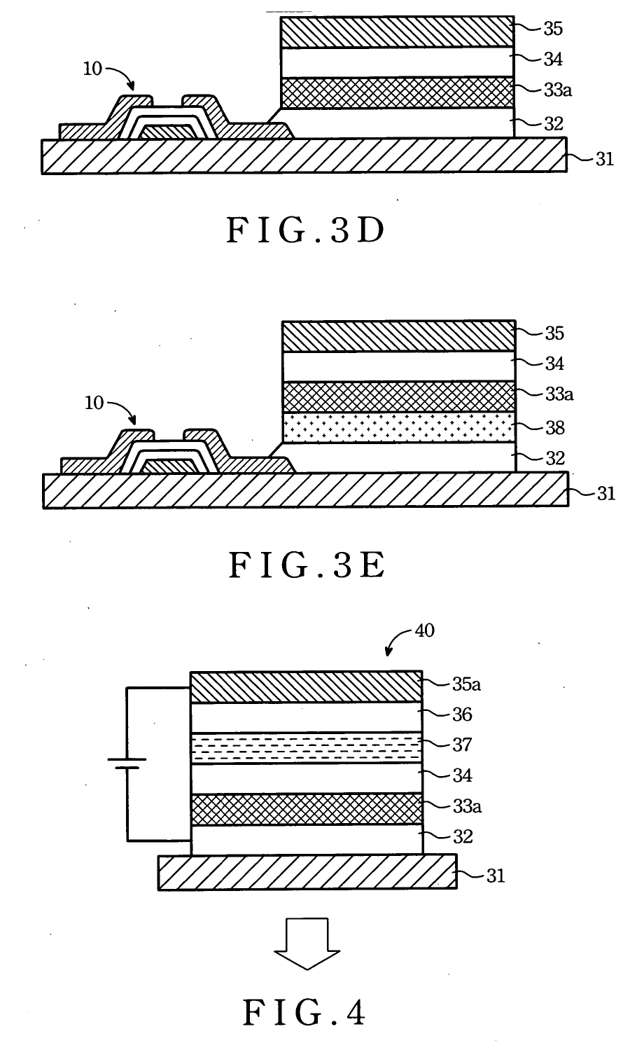

FIG. 5 shows a top emitting OLED 50 in accordance with the present invention. The first electrode 32 and the second electrode 35b of the OLED 50 may be formed of transparent conductive material. It is noted that for preventing the influence of high temperature process, the first electrode 32 on the substrate 31a includes a transparent material rather than a metal. The substrate 31a may be formed of transparent material or some non-transparent material, such as non-transparent plastic or metal, for shielding the illumination. A reflective layer 39 formed of metal may be formed between the substrate 31a and the first electrode 32 for reflecting the illumination from the emitting layer 34 so as to have the OLED 50 illuminating through the second electrode 35b outward. In addition, the electron transport layer 33a mixed with at least one n-type dopant may be formed between the first electrode 32 and the emitting layer 34.

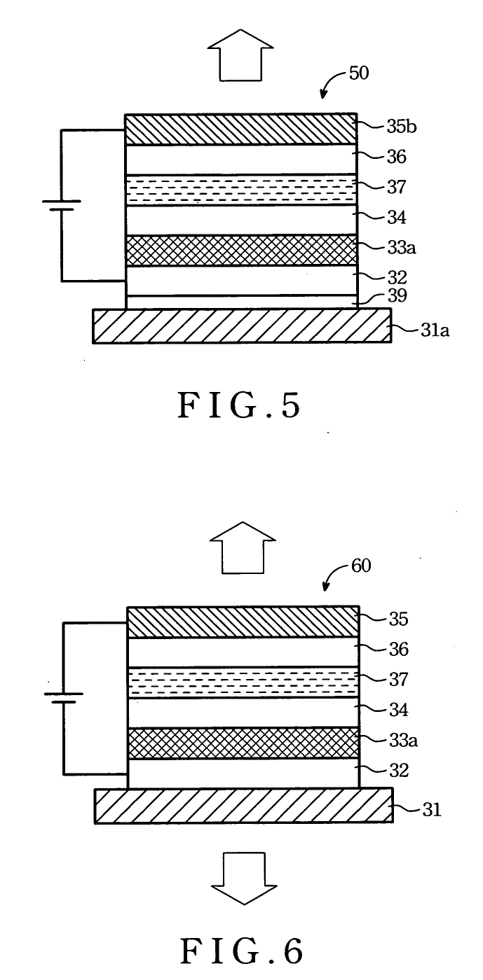

FIG. 6 shows a double emitting OLED 60 in accordance with the present invention. The first electrode 32, the second electrode 35, and the substrate 31 are all formed of transparent material. The electron transport layer 33a mixed with at least one n-type dopant is formed between the first electrode 32 and the emitting layer 34.

It is noted that the organic layers such as the hole injecting layer, the hole transport layer, the emitting layer, the electron transport layer, or the electron injecting layer may be formed by using evaporation method. The dopant may be added to the layers by co-evaporating with the organic layer or by using ion implantation method. In addition, the electron injecting layer may be added with at least one n-type dopant for increasing electron supply, and the hole injecting layer may be added with at least one p-type dopant for increasing hole supply. The inorganic portions, such as the metal electrode, may be formed by using evaporation method or sputtering method.

In compared with the traditional technology, it is obvious that the OLED and the method for manufacturing the OLED in the present invention have the advantages of simple process, low operation voltage, and high illumination efficiency.

While the embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. An organic light-emitting diode (OLED) comprising:
a first electrode;
an electron transport layer, formed on the first electrode, having an n-type dopant;
an emitting layer formed on the electron transport layer; and
a second electrode formed on the emitting layer.

2. The OLED of claim 1, wherein the n-type dopant includes an alkali halide, an alkaline-earth halide, an alkali oxide, or a metal-carbonate compound.

3. The OLED of claim 1, further comprising an electron injecting layer formed between the first electrode and the electron transport layer, wherein the electron injecting layer includes an alkali halide, an alkaline-earth halide, an alkali oxide, or a metal-carbonate compound.

4. The OLED of claim 1, wherein the first electrode includes indium-tin-oxide (ITO) or indium-zinc-oxide (IZO).

5. The OLED of claim 1, further comprising an electron injecting layer formed between the first electrode and the electron transport layer, wherein the electron injecting layer includes a metallic compound.

6. The OLED of claim 1, wherein the second electrode includes indium-tin-oxide (ITO) or indium-zinc-oxide (IZO).

7. The OLED of claim 1, wherein the second electrode includes a reflective conductive material.

8. The OLED of claim 1, further comprising a hole transport layer formed between the emitting layer and the second electrode.

9. The OLED of claim 8, wherein the second electrode has a work function substantially equal to a highest occupied molecular orbit (HOMO) level of the hole transport layer

10. The OLED of claim 8, further comprising a hole injecting layer formed between the hole transport layer and the second electrode.

11. The OLED of claim 1, further comprising a reflective layer, wherein the first electrode is located between the reflective layer and the electron transport layer.

12. A method for manufacturing an organic light-emitting diode (OLED), comprising:
forming a first electrode on a substrate, wherein the first electrode includes a transparent conductive material;
forming an electron transport layer having at least one n-type dopant on the first electrode;
forming an emitting layer on the electron transport layer; and
forming a second electrode on the emitting layer.

13. The method of claim 12, wherein the n-type dopant includes an alkali halide, an alkaline-earth halide, an alkali oxide, or a metal-carbonate compound.

14. The method of claim 12, wherein the transparent conductive material includes indium-tin-oxide (ITO) or indium-zinc-oxide (IZO).

15. The method of claim 12, further comprising forming an electron injecting layer on the first electrode before the step of forming the electron transport layer, wherein the electron injecting layer includes an alkali halide, an alkaline-earth halide, an alkali oxide or a metal-carbonate compound.

16. The method of claim 12, further comprising forming a hole transport layer on the emitting layer before the step of forming the second electrode.

17. The method of claim 12, further comprising forming a hole injecting layer on the emitting layer before the step of forming the second electrode.

18. The method of claim 12, further comprising forming an electron injecting layer on the first electrode before the step of forming the electron transport layer, wherein the electron injecting layer includes metallic compound.

19. The method of claim 12, further comprising forming a reflective layer on the substrate before the step of forming the first electrode.
